(19) United States
(12) Patent Application Publication
(10) Pub. No.: US 2020/0111942 A1
(43) Pub. Date: Apr. 9, 2020

(54) CORROSION RESISTANT THERMOELECTRIC DEVICES

(71) Applicant: Phononic, Inc., Durham, NC (US)

(72) Inventors: Robert Therrien, Cary, NC (US); Alex Guichard, Apex, NC (US); Brooks Henderson, Durham, NC (US); Steve Seel, Cary, NC (US); Ananthakrishnan Narayanan, Durham, NC (US); Pablo Cantu, Raleigh, NC (US); Kevin Oswalt, Durham, NC (US); Swathi Upadhayay, Durham, NC (US); Rajesh Bikky, Durham, NC (US); Jason Reed, Chapel Hill, NC (US)

(21) Appl. No.: 16/295,699

(22) Filed: Mar. 7, 2019

Related U.S. Application Data
(60) Provisional application No. 62/743,322, filed on Oct. 9, 2018.

(51) Int. Cl. H01L 35/32; H01L 35/34; B32B 15/04

(52) U.S. Cl. CPC H01L 35/32; H01L 35/34; B32B 2307/714; B32B 2307/752; B32B 15/04

(57) ABSTRACT

Corrosion resistant thermoelectric devices and methods of manufacturing them are disclosed herein. In some embodiments, a corrosion resistant thermoelectric device includes a semiconductor layer; a corrosion resistant top metallization layer formed on a top surface of the semiconductor layer; and a corrosion resistant bottom metallization layer formed on a bottom surface of the semiconductor layer, where the bottom surface of the semiconductor layer is opposite of the top surface of the semiconductor layer. In this way, the corrosion resistance of the device is provided by the intrinsic properties of the materials used rather than provided by the packaging or a surface coating. As such, the corrosion protection can be ensured and verified by control of the materials used to construct the device. This approach is also less susceptible to damage from shipment, handling, integration, attachment, and assembly operations because the corrosion protection is intrinsic to the materials used in construction.

### RELATED APPLICATIONS

This application claims the benefit of provisional patent application Ser. No. 62/743,322, filed Oct. 9, 2018, the disclosure of which is hereby incorporated herein by reference in its entirety.

### FIELD OF THE DISCLOSURE

The present disclosure relates to thermoelectric devices and their operation.

### BACKGROUND

Thermoelectric devices are widely used in temperature control, heating, cooling, refrigeration, power generation, and energy harvesting applications. In these applications, thermoelectric devices are operated in ambient conditions that frequently include gas-phase water (steam), humidity (water vapor) and liquid water. When operated in these conditions, the presence of liquid water by itself and in combination with electrical potential (voltage) in the device cause corrosion, which leads to dissolution, migration, and/or degradation of the metals used to construct the device and eventual device failure.

When operated in environments containing water vapor or steam, thermoelectric devices cause liquid water to condense on the metallic structures in the device. The presence of liquid water causes corrosion, leading to dissolution of metal layers in the device that are used to carry electrical current and/or bond elements of the device together. The rate and extent of the corrosion is increased by the mechanism of electrolysis, which occurs in the presence of condensed water and with a voltage or electrical potential difference between conductive structures in the device. When corrosion occurs, the device's electrical and thermal performance degrades, eventually resulting in device failure. As such, improved thermoelectric devices are needed.

### SUMMARY

Corrosion resistant thermoelectric devices and methods of manufacturing them are disclosed herein. In some embodiments, a corrosion resistant thermoelectric device includes a semiconductor layer; a corrosion resistant top metallization layer formed on a top surface of the semiconductor layer; and a corrosion resistant bottom metallization layer formed on a bottom surface of the semiconductor layer, where the bottom surface of the semiconductor layer is opposite of the top surface of the semiconductor layer. In this way, the corrosion resistance of the device is provided by the intrinsic properties of the materials used rather than provided by the packaging or a surface coating. As such, the corrosion protection can be ensured and verified by control of the materials used to construct the device. Also, this approach is compatible with high volume manufacturing methods such as metal film deposition and patterning, and is well controlled, repeatable, and automatable. Also, this approach does not reduce the thermal budget or temperature limit for assembly into the next level system and is compatible with plasma cleaning after integration, attachment, and assembly. This approach is also less susceptible to damage from shipment, handling, integration, attachment, and assembly operations because the corrosion protection is intrinsic to the materials used in construction.

In some embodiments, the corrosion resistant top metallization layer includes a corrosion resistant top ohmic contact layer. In some embodiments, the corrosion resistant top metallization layer also includes a corrosion resistant top adhesion layer formed on the top surface of the semiconductor layer. The corrosion resistant top ohmic contact layer is formed on a top surface of the corrosion resistant top adhesion layer.

In some embodiments, the corrosion resistant top metallization layer also includes a corrosion resistant top attach layer formed on the top surface of the corrosion resistant top ohmic contact layer. In some embodiments, the corrosion resistant bottom metallization layer includes a corrosion resistant bottom ohmic contact layer. In some embodiments, the corrosion resistant bottom metallization layer also includes a corrosion resistant bottom adhesion layer formed on the bottom surface of the semiconductor layer. The corrosion resistant bottom ohmic contact layer is formed on a bottom surface of the corrosion resistant bottom adhesion layer.

In some embodiments, the corrosion resistant bottom metallization layer also includes a corrosion resistant bottom attach layer formed on the bottom surface of the corrosion resistant bottom ohmic contact layer.

In some embodiments, the semiconductor layer includes bismuth telluride. In some embodiments, the corrosion resistant top ohmic contact layer and the corrosion resistant bottom ohmic contact layer include at least one of the group consisting of ruthenium, rhodium, palladium, osmium, iridium, platinum, and gold. In some embodiments, at least one of the corrosion resistant top ohmic contact layer and the corrosion resistant bottom ohmic contact layer is iridium.

In some embodiments, a thickness of the corrosion resistant top metallization layer and a thickness of the corrosion resistant bottom metallization layer are in the range of 50 nanometers to 1 micrometer. In some embodiments, at least one of the thickness of the corrosion resistant top metallization layer and the thickness of the corrosion resistant bottom metallization layer is in the range of 250 nanometers to 500 nanometers.

In some embodiments, a thickness of the corrosion resistant top attach layer and a thickness of the corrosion resistant bottom attach layer is in the range of 10 nanometers to 5 micrometers. In some embodiments, at least one of the thickness of the corrosion resistant top attach layer and the thickness of the corrosion resistant bottom attach layer is in the range of 50 nanometers to 250 nanometers.

In some embodiments, the corrosion resistant top attach layer and the corrosion resistant bottom attach layer include at least one of the group consisting of ruthenium, rhodium, palladium, osmium, iridium, platinum, and gold. In some embodiments, at least one of the corrosion resistant top attach layer and the corrosion resistant bottom attach layer is gold.

In some embodiments, the corrosion resistant top adhesion layer and the corrosion resistant bottom adhesion layer include at least one of titanium, titanium nitride, or chromium. In some embodiments, at least one of the corrosion resistant top adhesion layer and the corrosion resistant bottom adhesion layer is titanium.

In some embodiments, the corrosion resistant thermoelectric device also includes a substrate layer and a corrosion resistant substrate metallization layer formed on the substrate layer.

In some embodiments, the corrosion resistant substrate metallization layer includes a substrate adhesion layer formed on the substrate layer; a substrate conducting layer formed on the substrate adhesion layer; a substrate diffusion layer formed on the substrate conducting layer; and a substrate attach layer formed on the substrate diffusion layer.

In some embodiments, the substrate conducting layer is gold. In some embodiments, a thickness of the substrate conducting layer is in the range of 1 micrometer to 50 micrometers. In some embodiments, the thickness of the substrate conducting layer is in the range of 2 micrometers to 10 micrometers.

In some embodiments, the substrate diffusion layer is platinum. In some embodiments, a thickness of the substrate diffusion layer is in the range of 10 nanometers to 1 micrometer. In some embodiments, the thickness of the substrate diffusion layer is in the range of 100 nanometers to 500 nanometers.

In some embodiments, the substrate attach layer is gold. In some embodiments, a thickness of the substrate attach layer is in the range of 10 nanometers to 5 micrometers. In some embodiments, the thickness of the substrate attach layer is in the range of 50 nanometers to 250 nanometers.

In some embodiments, the substrate adhesion layer includes at least one of the group consisting of titanium, titanium nitride, chromium. In some embodiments, the substrate adhesion layer is titanium.

In some embodiments, the corrosion resistant substrate metallization layer is attached to one of the corrosion resistant top metallization layer and the corrosion resistant bottom metallization layer with a corrosion resistant solder. In some embodiments, the corrosion resistant solder includes at least one of the group comprising: indium, tin, bismuth, antimony, gold, and germanium. In some embodiments, the corrosion resistant solder includes at least one of the group comprising: tin antimony, gold tin, tin bismuth, and gold germanium.

In some embodiments, the corrosion resistant thermoelectric device also includes a corrosion resistant bonding post formed on the substrate layer. In some embodiments, the corrosion resistant bonding post includes a core including at least one of the group consisting of copper, titanium, and nickel.

In some embodiments, the corrosion resistant bonding post also includes a terminating layer covering an entire surface of the core, where the terminating layer includes at least one of gold or nickel. In some embodiments, a thickness of the terminating layer is a maximum of 5 micrometers.

In some embodiments, a method of manufacturing a corrosion resistant thermoelectric device as disclosed above. In some embodiments, the method includes at least one of sputtering, evaporation, and metalorganic chemical vapor deposition of at least one of the layers.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a corrosion resistant thermoelectric device, according to some embodiments of the current disclosure;

FIG. 2 illustrates additional details of the corrosion resistant toplbottom metallization layers, according to some embodiments of the current disclosure;

FIGS. 3A and 3B illustrate additional details of the corrosion resistant substrate metallization layer, according to some embodiments of the current disclosure;

FIGS. 4A and 4B illustrate additional details of the corrosion resistant bonding post, according to some embodiments of the current disclosure;

FIG. 5 illustrates lifetime data of the corrosion resistant thermoelectric device compared to a standard thermoelectric device, according to some embodiments of the current disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

Thermoelectric devices are solid state semiconductor devices that, depending on the particular application, can be either thermoelectric coolers or thermoelectric generators. Thermoelectric coolers are solid state semiconductor devices that utilize the Peltier effect to transfer heat from one side of the device to the other, thereby creating a cooling effect on the cold side of the device. Because the direction of heat transfer is determined by the polarity of an applied voltage, thermoelectric devices can be used generally as temperature controllers. Similarly, thermoelectric generators are solid state semiconductor devices that utilize the Seebeck effect to convert heat (i.e., a temperature difference from one side of the device to the other) directly into electrical energy. A thermoelectric device includes at least one N-type leg and at least one P-type leg. The N-type legs and the P-type legs are formed of a thermoelectric material (i.e., a semiconductor material having sufficiently strong thermoelectric properties). In order to effect thermoelectric cooling, an electrical current is applied to the thermoelectric device. The direction of current transference in the N-type legs and the P-type legs is parallel to the direction of heat transference in the thermoelectric device. As a result, cooling occurs at the top surface of the thermoelectric device, and the heat is released at the bottom surface of the thermoelectric device.

Thermoelectric systems that use thermoelectric devices are advantageous compared to non-thermoelectric systems because they lack moving mechanical parts, have long lifespans, and can have small sizes and flexible shapes.

Thermoelectric devices are widely used in temperature control, heating, cooling, refrigeration, power generation, and energy harvesting applications. In these applications, thermoelectric devices are operated in ambient conditions that frequently include steam (gas phase water), humidity (water vapor) and liquid water. When operated in these conditions, the presence of liquid water by itself and in combination with electrical potential (voltage) in the device cause corrosion, which leads to dissolution, migration, and/or degradation of the metals used to construct the device and eventual device failure.

When operated in environments containing water vapor or steam, thermoelectric devices cause liquid water to condense on the metallic structures in the device. The presence of liquid water causes corrosion, leading to dissolution of metal layers in the device that are used to carry electrical current and/or bond elements of the device together. The rate and extent of the corrosion is increased by the mechanism of electrolysis, which occurs in the presence of condensed water and with a voltage or electrical potential difference between conductive structures in the device. When corrosion occurs, the device's electrical and thermal performance degrades, eventually resulting in device failure. As such, improved thermoelectric devices are needed.

To prevent these failures, methods such as packaging the device in a water-free package, sealing the device, and coating the device with water resistant materials have been applied. The disadvantages of these methods are detailed below.

The metal layers in thermoelectric devices are used to create electrical conductors, conduct heat from the semiconductor thermoelectric elements to the substrate, create an ohmic contact between the metal and the semiconductor, create a diffusion barrier to prevent metals from diffusing into the semiconductor thermoelectric elements and causing device degradation, and provide a layer to wet to the solder during device assembly.

To prevent corrosion, thermoelectric devices are operated in a sealed package with a controlled dry atmosphere, such as by sealing the devices in a hermetic package. This approach prevents corrosion by excluding liquid water, water vapor or steam from the area around the device. The disadvantage to this approach is that it requires materials and seals that are impermeable to liquid water, water vapor or steam and remain impermeable throughout the device operating lifetime. Packages that incorporate these materials and seals are bulky and expensive.

Another approach is by coating or sealing the surfaces or edges of the device with a layer or layers to prevent water from reaching the metal layers of the device. This approach slows the rate of corrosion by reducing the amount water, steam and water vapor reaching the metal surfaces of the device. One disadvantage to this approach is that the coating materials are permeable to water vapor and steam and eventually detach from the surfaces they are designed to protect, allowing liquid water to accumulate on the surfaces which results in corrosion. Another disadvantage to this approach is that the coating reduces performance of the device because it increases the parasitic thermal conductivity of the thermoelectric elements in the device. Another disadvantage of this approach is that the sealing and coating methods are labor intensive and difficult to apply. Another disadvantage of this approach is that the sealing and coating methods are difficult to inspect. A missing area of coating, a pinhole, gap, or crack will render the seal or coating ineffective at preventing water ingress and subsequent corrosion. During shipment, handling, integration, attachment and assembly operations, it is possible to damage the coating or sealing and render the seal or coating ineffective at preventing water ingress and subsequent corrosion. Another disadvantage of this approach is that there is generally an upper limit to the temperature and time (thermal budget) that may be applied to the devices once the coating or sealing has been applied. This limit can make integration, attachment, and assembly into the next-level system more difficult or expensive. Another disadvantage of this approach is that the coating or sealing may not be compatible with plasma cleaning after integration. There is generally a requirement to be able to plasma clean the device after attachment and integration in the next level assembly. Another disadvantage of this approach is that it is device geometry dependent. Some designs may not have a continuous edge (for example, a device with an interior hole) around which a seal may be applied. Some designs may have narrow spacing between semiconductor elements which will preclude the use of a coating because there is not enough space between elements to allow the coating to penetrate and coat the interior surfaces. Some designs may have electrical pads, bonding posts or substrate surfaces that must not be coated so that electrical and/or thermal connections may be made. These areas must be masked before coating or sealing, or else patterned after coating or sealing, to prevent coverage. The unsealed pads, posts and surfaces of the device will not be covered by the coating or protected by the sealing and may corrode if operated in a humid environment.

Corrosion resistant thermoelectric devices and methods of manufacturing them are disclosed herein. In some embodiments, a corrosion resistant thermoelectric device includes a semiconductor layer; a corrosion resistant top metallization layer formed on a top surface of the semiconductor layer; and a corrosion resistant bottom metallization layer formed on a bottom surface of the semiconductor layer, where the bottom surface of the semiconductor layer is opposite of the top surface of the semiconductor layer. In this way, the corrosion resistance of the device is provided by the intrinsic properties of the materials used rather than provided by the packaging or a surface coating. As such, the corrosion protection can be ensured and verified by control of the materials used to construct the device. Also, this approach is compatible with high volume manufacturing methods such as metal film deposition and patterning, and is well controlled, repeatable, and automatable. Also, this approach does not reduce the thermal budget or temperature limit for assembly into the next level system and is compatible with plasma cleaning after integration, attachment, and assembly. The next level assembly is the device or product that the thermoelectric device is included in such as a laser diode. This approach is also less susceptible to damage from shipment, handling, integration, attachment, and assembly operations because the corrosion protection is intrinsic to the materials used in construction.

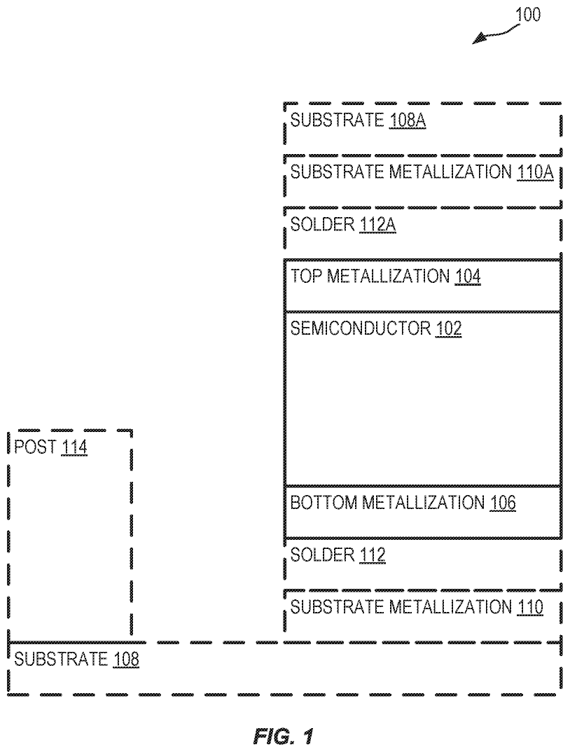

FIG. 1 illustrates a corrosion resistant thermoelectric device 100, according to some embodiments of the current disclosure. The corrosion resistant thermoelectric device 100 includes a semiconductor layer 102; a corrosion resistant top metallization layer 104 formed on a top surface of the semiconductor layer 102; and a corrosion resistant bottom metallization layer 106 formed on a bottom surface of the semiconductor layer 102, where the bottom surface of the semiconductor layer 102 is opposite of the top surface of the semiconductor layer 102.

FIG. 1 also illustrates a substrate 108 with a corrosion resistant substrate metallization layer 110 formed on the substrate 108. Solder 112 is used to attach the corrosion resistant bottom metallization layer 106 to the corrosion resistant substrate metallization layer 110. FIG. 1 also illustrates a corrosion resistant bonding post 114 formed on the substrate 108.

Similar to the discussion above, FIG. 1 also illustrates another or top substrate 108A with a top substrate metallization 110A. Solder 112A is used to attach the corrosion resistant top metallization layer 104 to the corrosion resistant substrate metallization layer 110A.

In some embodiments, the corrosion resistant thermoelectric device 100 is made corrosion resistant by incorporating metals that are highly corrosion resistant such as ruthenium, rhodium, palladium, osmium, iridium, platinum, and gold. Also, materials such as cobalt and phosphorus can be used. These metals are used in place of metals such as nickel, copper, and others that readily corrode when in contact with water and voltage. One advantage of this approach is that the corrosion resistance of the corrosion resistant thermoelectric device 100 is provided by the intrinsic properties of the materials used in the corrosion resistant thermoelectric device 100 rather than provided by the packaging or a surface coating. Thus the corrosion protection can be ensured and verified by control of the materials used to construct the corrosion resistant thermoelectric device 100. Another advantage of the approach is that it is compatible with high volume manufacturing methods such as metal film deposition and patterning, and is well controlled, repeatable, and automatable. Another advantage of the approach is that it does not reduce the thermal budget or temperature limit for assembly into the next level system. It is also compatible with plasma cleaning after integration, attachment, and assembly. Another advantage of the approach is that it is less susceptible to damage from shipment, handling, integration, attachment, and assembly operations because the corrosion protection is intrinsic to the materials used in construction.

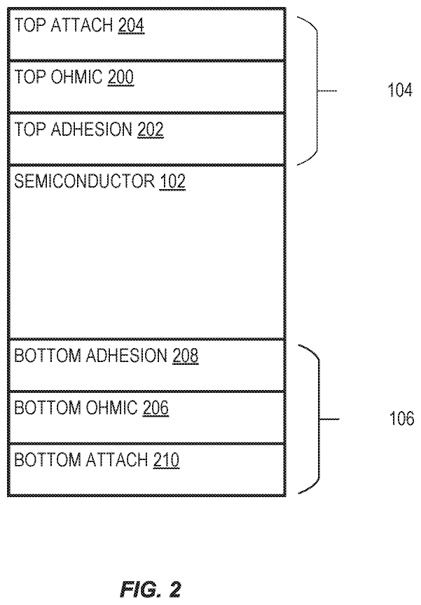

FIG. 2 illustrates additional details of the corrosion resistant top/bottom metallization layers 104/106, according to some embodiments of the current disclosure. FIG. 2 shows that the corrosion resistant top metallization layer 104 includes a corrosion resistant top ohmic contact layer 200, a corrosion resistant top adhesion layer 202 formed on the top surface of the semiconductor layer 102, and a corrosion resistant top attach layer 204 formed on the top surface of the corrosion resistant top ohmic contact layer 200.

Similarly, FIG. 2 shows that the corrosion resistant bottom metallization layers 106 includes a corrosion resistant bottom ohmic contact layer 206, a corrosion resistant bottom adhesion layer 208 formed on the bottom surface of the semiconductor layer 102, and a corrosion resistant bottom attach layer 210 formed on the bottom surface of the corrosion resistant bottom ohmic contact layer 206.

In some embodiments, the corrosion resistant top/bottom ohmic contact layers 200/206 on the semiconductor layer 102 are chosen from ruthenium, rhodium, palladium, osmium, iridium, platinum, and gold in the range of 50 nanometers-1 micrometer thick and preferably in the range of 250 nanometers-500 nanometers thick. These layers may be deposited by physical vapor deposition, evaporation, electroplating, or any of a number of methods. In some embodiments, the corrosion resistant top/bottom attach layers 204/210 are gold applied in the range of 10 nanometers to 5 micrometers thick, and preferably in the range of 50 nanometers to 250 nanometers thick. The purpose of the corrosion resistant top/bottom attach layers 204/210 is to wet to the solder 112 during device assembly.

In some embodiments, the corrosion resistant top/bottom adhesion layers 202/208 are made of titanium, titanium nitride, and/or chromium. These corrosion resistant top/bottom adhesion layers 202/208 are used between the corrosion resistant top/bottom ohmic contact layers 200/206 and the semiconductor layer 102. In some embodiments, the corrosion resistant top/bottom ohmic contact layers 200/206 have a thickness in the range of 1 nanometer to 100 nanometers and preferably in the range of 1 nanometer to 10 nanometers.

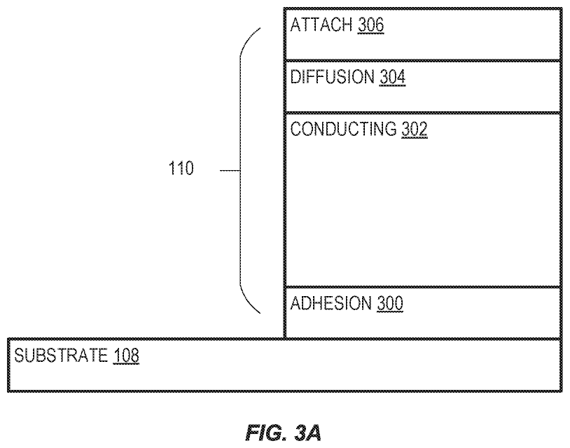

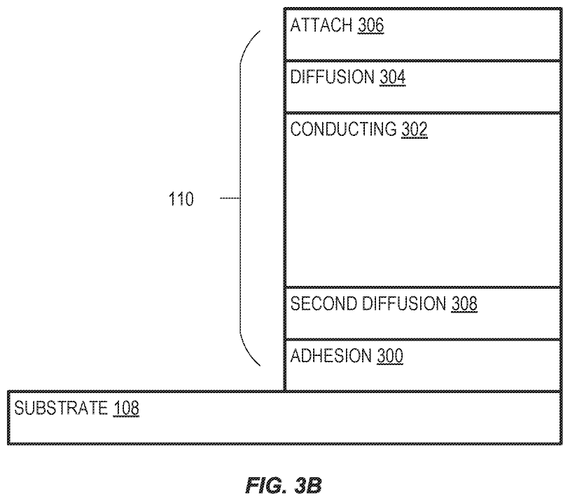

FIGS. 3A and 3B illustrate additional details of the corrosion resistant substrate metallization layer 110, according to some embodiments of the current disclosure. FIG. 3A includes the substrate 108 and the corrosion resistant substrate metallization layer 110. The corrosion resistant substrate metallization layer 110 includes a substrate adhesion layer 300 formed on the substrate layer 108; a substrate conducting layer 302 formed on the substrate adhesion layer 300; a substrate diffusion layer 304 formed on the substrate conducting layer 302; and a substrate attach layer 306 formed on the substrate diffusion layer 304.

The corrosion resistant substrate metallization layer 110 on the substrate 108 includes materials chosen from ruthenium, rhodium, palladium, osmium, iridium, platinum, and gold. In some embodiments, two or more different layers are used to provide two functions: sufficient electrical and thermal conductivity in one or more of the layers and to provide a diffusion barrier with another layer or layers to prevent the solder 112 from diffusing into and reacting with the first layers. In some embodiments, there is only one trace metallization layer if the solder material 112 and the process are chosen such that the process does not react with the corrosion resistant substrate metallization layer 110.

For example, one preferable layer sequence is the substrate conducting layer 302, the substrate diffusion layer 304, and the substrate attach layer 306. In some embodiments, these layers are made of gold, platinum, and gold, respectively. The purpose of the substrate conducting layer 302 is to provide an electrical and thermal conductor in the device. This substrate conducting layer 302 is in the range of 1 micrometer to 50 micrometers thick and preferably in the range of 2 micrometers to 10 micrometers thick. The purpose of the substrate diffusion layer 304 is to provide a diffusion barrier between the solder 112 and the substrate conducting layer 302. This substrate diffusion layer 304 is in the range of 10 nanometers to 1 micrometer and preferably in the range of 100 nanometers to 500 nanometers.

The purpose of the substrate attach layer 306 is to provide a surface that wets to the solder 112 during device assembly. This substrate attach layer 306 is in the range of 10 nanometers to 5 micrometers and preferably in the range of 50 nanometers to 250 nanometers thick.

In some embodiments, the solder 112 can be any one of a number of solders containing varying amounts of such elements as indium, tin, bismuth, antimony, gold, germanium such as tin antimony, gold tin, tin bismuth, and gold germanium among others. One such solder 112 is gold tin with gold weight 75-80 percent and tin weight 20-25 percent, preferably with gold weight 78 percent and tin weight 22 percent. Another such solder 112 is tin antimony with tin weight 80-99.5 percent and antimony weight 0.5-20 percent, preferably with tin weight 90-99 percent and antimony weight 1-10 percent.

In some embodiments, the substrate adhesion layer 300 is made of titanium, titanium nitride, and/or chromium. The substrate adhesion layer 300 is used between the corrosion resistant substrate metallization layer 110 and the substrate 108. The substrate adhesion layer 300 has a thickness in the range of 10 nanometers to 1 micrometer and preferably in the range of 50 nanometers to 250 nanometers.

FIG. 3B is similar, but also includes a second substrate diffusion layer 308 formed between the substrate adhesion layer 300 and the substrate conducting layer 302. This second substrate diffusion layer 308 may be a platinum layer. In some embodiments, this second substrate diffusion layer 308 prevents the substrate conducting layer 302 from reacting with the substrate 108.

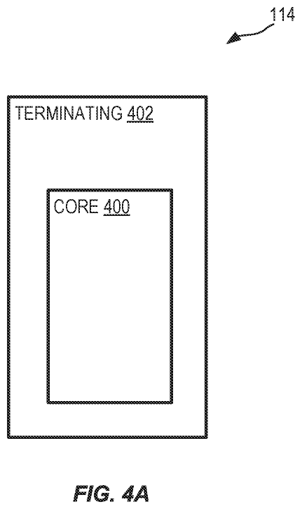

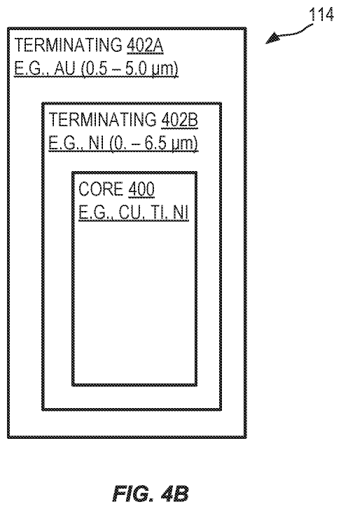

FIGS. 4A and 4B illustrate additional details of the corrosion resistant bonding post 114, according to some embodiments of the current disclosure. The corrosion resistant bonding post 114 is a passive component that is attached to the substrate 108 such as a bottom ceramic. The corrosion resistant bonding post 114 is used for electrical connection to the corrosion resistant thermoelectric device 100. In some embodiments, the corrosion resistant bonding post 114 may consist of a copper, titanium, or nickel core 400, with either a nickel+gold or just gold terminating layer 402 covering the entire surface. FIG. 4B illustrates an embodiment where the terminating layer 402 includes an outer terminating layer 402A which is e.g., gold with a thickness of 0.5-5.0 micrometers. Additionally, FIG. 4B includes an inner terminating layer 402B which is, e.g., nickel with a thickness of 0-6.5 micrometers. Titanium is more corrosion resistant than copper. In some embodiments, the terminating layer 402 has a maximum thickness of 5 micrometers and would be used to protect the copper, titanium and/or nickel that is used.

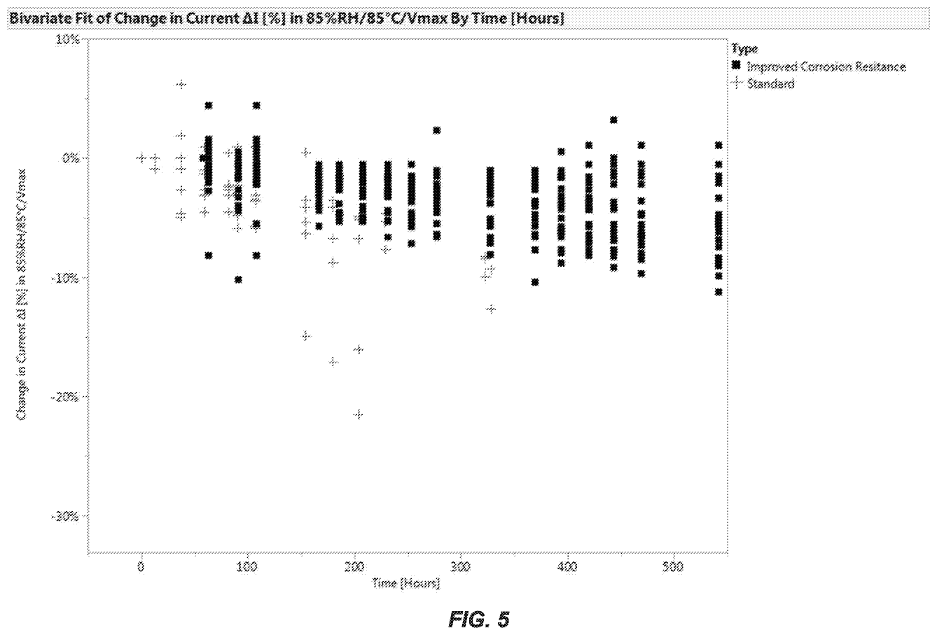

FIG. 5 illustrates lifetime data of the corrosion resistant thermoelectric device 100 compared to a standard thermoelectric device, according to some embodiments of the current disclosure. The graph plots the change in operating current in highly accelerated stress conditions (temperature 85° C., ambient humidity 85% Relative Humidity (RH), operating bias 5.2 Volts (V)) over time. The mean time to failure for the standard device was 179 hours compared to a projected 912 hours for the corrosion resistant thermoelectric device 100.

Those skilled in the art will recognize improvements and modifications to the preferred embodiments of the present disclosure. All such improvements and modifications are considered within the scope of the concepts disclosed herein and the claims that follow.

1. A corrosion resistant thermoelectric device comprising:
a semiconductor layer;
a corrosion resistant top metallization layer formed on a top surface of the semiconductor layer; and
a corrosion resistant bottom metallization layer formed on a bottom surface of the semiconductor layer, where the bottom surface of the semiconductor layer is opposite of the top surface of the semiconductor layer.

2. The corrosion resistant thermoelectric device of claim 1 wherein the corrosion resistant top metallization layer comprises:
a corrosion resistant top ohmic contact layer.

3. The corrosion resistant thermoelectric device of claim 2 wherein the corrosion resistant top metallization layer further comprises:
a corrosion resistant top adhesion layer formed on the top surface of the semiconductor layer; and
the corrosion resistant top ohmic contact layer is formed on a top surface of the corrosion resistant top adhesion layer.

4. The corrosion resistant thermoelectric device of claim 3 wherein the corrosion resistant top metallization layer further comprises:
a corrosion resistant top attach layer formed on the top surface of the corrosion resistant top ohmic contact layer.

5. The corrosion resistant thermoelectric device of claim 4 wherein the corrosion resistant bottom metallization layer comprises:
a corrosion resistant bottom ohmic contact layer.

6. The corrosion resistant thermoelectric device of claim 5 wherein the corrosion resistant bottom metallization layer further comprises:
a corrosion resistant bottom adhesion layer formed on the bottom surface of the semiconductor layer; and
the corrosion resistant bottom ohmic contact layer is formed on a bottom surface of the corrosion resistant bottom adhesion layer.

7. The corrosion resistant thermoelectric device of claim 6 wherein the corrosion resistant bottom metallization layer further comprises:
a corrosion resistant bottom attach layer formed on the bottom surface of the corrosion resistant bottom ohmic contact layer.

8. The corrosion resistant thermoelectric device of claim 7 wherein the semiconductor layer comprises bismuth telluride.

9. The corrosion resistant thermoelectric device of claim 8 wherein the corrosion resistant top ohmic contact layer and the corrosion resistant bottom ohmic contact layer comprises at least one of the group consisting of ruthenium, rhodium, palladium, osmium, iridium, platinum, and gold.

10. The corrosion resistant thermoelectric device of claim 9 wherein at least one of the corrosion resistant top ohmic contact layer and the corrosion resistant bottom ohmic contact layer comprises iridium.

11. The corrosion resistant thermoelectric device of claim 10 wherein a thickness of the corrosion resistant top metallization layer and a thickness of the corrosion resistant bottom metallization layer is in the range of 50 nanometers to 1 micrometer.

12. The corrosion resistant thermoelectric device of claim 11 wherein at least one of the thickness of the corrosion resistant top metallization layer and the thickness of the corrosion resistant bottom metallization layer is in the range of 250 nanometers to 500 nanometers.

13. The corrosion resistant thermoelectric device of claim 12 wherein a thickness of the corrosion resistant top attach layer and a thickness of the corrosion resistant bottom attach layer is in the range of 10 nanometers to 5 micrometers.

14. The corrosion resistant thermoelectric device of claim 13 wherein at least one of the thickness of the corrosion resistant top attach layer and the thickness of the corrosion resistant bottom attach layer is in the range of 50 nanometers to 250 nanometers.

15. The corrosion resistant thermoelectric device of claim 14 wherein the corrosion resistant top attach layer and the corrosion resistant bottom attach layer comprises at least one of the group consisting of ruthenium, rhodium, palladium, osmium, iridium, platinum, and gold.

16. The corrosion resistant thermoelectric device of claim 15 wherein at least one of the corrosion resistant top attach layer and the corrosion resistant bottom attach layer comprises gold.

17. The corrosion resistant thermoelectric device of claim 16 wherein the corrosion resistant top adhesion layer and the corrosion resistant bottom adhesion layer comprises at least one of the group consisting of titanium, titanium nitride, chromium.

18. The corrosion resistant thermoelectric device of claim 17 wherein at least one of the corrosion resistant top adhesion layer and the corrosion resistant bottom adhesion layer comprises titanium.

19. The corrosion resistant thermoelectric device of claim 18 further comprising:
a substrate layer; and
a corrosion resistant substrate metallization layer formed on the substrate layer.

20. The corrosion resistant thermoelectric device of claim 19 wherein the corrosion resistant substrate metallization layer comprises:
a substrate adhesion layer formed on the substrate layer;
a substrate conducting layer formed on the substrate adhesion layer;
a substrate diffusion layer formed on the substrate conducting layer; and
a substrate attach layer formed on the substrate diffusion layer.

21. The corrosion resistant thermoelectric device of claim 20 wherein the substrate conducting layer comprises gold.

22. The corrosion resistant thermoelectric device of claim 21 wherein a thickness of the substrate conducting layer is in the range of 1 micrometer to 50 micrometers.

23. The corrosion resistant thermoelectric device of claim 22 wherein the thickness of the substrate conducting layer is in the range of 2 micrometers to 10 micrometers.

24. The corrosion resistant thermoelectric device of claim 23 wherein the substrate diffusion layer comprises platinum.

25. The corrosion resistant thermoelectric device of claim 24 wherein a thickness of the substrate diffusion layer is in the range of 10 nanometers to 1 micrometer.

26. The corrosion resistant thermoelectric device of claim 25 wherein the thickness of the substrate diffusion layer is in the range of 100 nanometers to 500 nanometers.

27. The corrosion resistant thermoelectric device of claim 26 wherein the substrate attach layer comprises gold.

28. The corrosion resistant thermoelectric device of claim 24 wherein a thickness of the substrate attach layer is in the range of 10 nanometers to 5 micrometers.

29. The corrosion resistant thermoelectric device of claim 25 wherein the thickness of the substrate attach layer is in the range of 50 nanometers to 250 nanometers.

30. The corrosion resistant thermoelectric device of claim 29 wherein the substrate adhesion layer comprises at least one of the group consisting of titanium, titanium nitride, chromium.

31. The corrosion resistant thermoelectric device of claim 30 wherein the substrate adhesion layer comprises titanium.

32. The corrosion resistant thermoelectric device of claim 31 wherein the corrosion resistant substrate metallization layer is attached to one of the corrosion resistant top metallization layer and the corrosion resistant bottom metallization layer with a corrosion resistant solder.

33. The corrosion resistant thermoelectric device of claim 32 wherein the corrosion resistant solder comprises at least one of the group comprising: indium, tin, bismuth, antimony, gold, and germanium.

34. The corrosion resistant thermoelectric device of claim 33 wherein the corrosion resistant solder comprises at least one of the group comprising: tin antimony, gold tin, tin bismuth, and gold germanium.

35. The corrosion resistant thermoelectric device of claim 19 further comprising:
a corrosion resistant bonding post formed on the substrate layer.

36. The corrosion resistant thermoelectric device of claim 35 wherein the corrosion resistant bonding post comprises a core comprising at least one of the group consisting of copper, titanium, and nickel.

37. The corrosion resistant thermoelectric device of claim 36 wherein the corrosion resistant bonding post further comprises a terminating layer covering an entire surface of the core, where the terminating layer comprises at least one of the group consisting of gold and nickel.

38. The corrosion resistant thermoelectric device of claim 37 wherein a thickness of the terminating layer is a maximum of 5 micrometers.

39. A method of manufacturing a corrosion resistant thermoelectric device of claim 38.

40. The method of manufacturing of claim 39 comprising at least one of sputtering, evaporation, and metalorganic chemical vapor deposition of at least one of the layers.
